(19) United States
(12) Patent Application Publication
(10) Pub. No.: US 2012/0171852 A1
(43) Pub. Date: Jul. 5, 2012

(54) REMOTE HYDROGEN PLASMA SOURCE OF SILICON CONTAINING FILM DEPOSITION

(75) Inventors: Zheng Yuan, Cupertino, CA (US); Mandar B. Pandit, Santa Clara, CA (US); Francimar C. Schmitt, Santa Clara, CA (US); Yi Zheng, Sunnyvale, CA (US); Fan Yang, Sunnyvale, CA (US); Lipan Li, Foster City, CA (US); Alan Tso, San Jose, CA (US); Dustin W. Ho, Fremont, CA (US); Tom K. Cho, Los Altos, CA (US); Randhir Thakur, Fremont, CA (US)

(73) Assignee: APPLIED MATERIALS, INC

(21) Appl. No.: 13/266,978

(22) PCT Filed: Aug. 2, 2010
(86) PCT No.: PCT/US2010/044133

§ 371 Date: Mar. 14, 2012

Related U.S. Application Data
(60) Provisional application No. 61/240,191, filed on Sep. 4, 2009.

(51) Int. Cl. H01L 21/20; C23C 16/50

(52) U.S. Cl. 438/488; 118/723 R; 257/E21.09

(57) ABSTRACT

Methods for forming and treating a silicon containing layer in a thin film transistor structure or solar cell devices are provided. In one embodiment, a method for forming a silicon containing layer on a substrate includes providing a substrate into a processing chamber, providing a gas mixture having a silicon containing gas into the processing chamber, providing a hydrogen containing gas from a remote plasma source coupled to the processing chamber, applying a RF power less than 17.5 mWatt/cm² to the processing chamber, and forming a silicon containing layer on the substrate.

### BACKGROUND OF THE INVENTION

1. Field of the Invention

Embodiments of the present invention generally relate to methods for forming or treating a silicon film with hydrogen species from a remote plasma source. More particularly, this invention relates to methods for forming a silicon film with hydrogen species from a remote plasma source for thin film transistors devices or solar cell applications.

2. Description of the Related Art

Silicon layers, including amorphous silicon, microcrystalline silicon, polycrystalline silicon or other types of silicon, are widely used in semiconductor industry, solar cell applications and thin film transistor (TFT) liquid crystalline display (LCD) industry. Film qualities of the silicon layers often control the electrical performance of the devices and transistors where the silicon layers are formed. During film deposition, defects, contamination, or other sources of impurities may be present in the deposition plasma, thereby adversely affecting the film qualities of the resultant deposited film. Poor film quality and high defect density of the silicon films will adversely reduce product yield, film electronic mobility, and light conversion efficiency when used in solar cell applications.

Therefore, there is a need for an improved method of forming and treating a silicon containing film with improved film quality and low defect density.

### SUMMARY OF THE INVENTION

Methods for forming a silicon containing layer in a thin film transistor structure or solar cell devices are provided. In one embodiment, a method for forming a silicon containing layer on a substrate includes providing a substrate into a processing chamber, providing a reacting gas mixture having a silicon containing gas into the processing chamber, providing a hydrogen containing gas from a remote plasma source coupled to the processing chamber, applying a RF power less than 17.5 mWatts/cm² to the processing chamber, and forming a silicon containing layer on the substrate.

In another embodiment, an apparatus for forming a silicon containing layer for solar cell applications on a substrate includes a chamber body defining a processing region, a first remote plasma source configured to plasma dissociate a cleaning gas coupled to on the chamber body, a second remote plasma source configured to plasma dissociate a processing gas coupled to the chamber body, and at least conduit configured to supply the dissociated gas species from the first and the second remote plasma source through a gas distribution plate to the processing region.

In another embodiment, hydrogen is dissociated using at least one remote plasma source, then provided to a processing region of a processing chamber body, while one or more non-dissociated silicon containing gases are provided into the processing region of the chamber.

In yet another embodiment, a method for forming a silicon containing layer on a substrate includes providing a substrate into a processing chamber, performing a pretreatment process on the substrate surface, providing a reacting gas mixture having a silicon containing gas into the processing chamber, providing a hydrogen containing gas from a remote plasma source coupled to the processing chamber, applying a RF power less than 175 mWatts/cm² to the processing chamber to form a plasma in the gas mixture, forming a silicon containing layer on the substrate, and performing a post treatment process on the formed silicon containing layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a sectional view of the processing chamber that may provide a remote hydrogen plasma source in accordance with one embodiment of the present invention;

FIG. 2 depicts a schematic side-view of a tandem junction thin-film solar cell according to one embodiment of the invention;

FIG. 3 depicts a process flow diagram of one embodiment of a method of forming microcrystalline silicon layer that may be used in a device structure.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin film solar cells are generally formed from numerous types of films, or layers, put together in many different ways. Most films used in such devices incorporate a semiconductor element that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, and conductivity. Most of these films can be formed by use of a chemical vapor deposition process, which may include some degree of ionization or plasma formation.

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths compared to intrinsic layers having different degrees of crystallinity, such as microcrystalline or nanocrystalline silicon. For this reason, it is advantageous to use both types of layers to yield the broadest possible absorption characteristics.

Silicon and other semiconductors can be formed into solids having varying degrees of crystallinity. Solids having essentially no crystallinity are amorphous, and silicon with negligible crystallinity is referred to as amorphous silicon. Completely crystalline silicon is referred to as crystalline, polycrystalline, or monocrystalline silicon. Polycrystalline silicon is crystalline silicon including numerous crystal grains separated by grain boundaries. Monocrystalline silicon is a single crystal of silicon. Solids having partial crystallinity, that is a crystal fraction between about 5% and about 95%, are referred to as nanocrystalline or microcrystalline, generally referring to the size of crystal grains suspended in an amorphous phase. Solids having larger crystal grains are referred to as microcrystalline, whereas those with smaller crystal grains are nanocrystalline. It should be noted that the term “crystalline silicon” may refer to any form of silicon having a crystal phase, including microcrystalline, nanocrystalline, monocrystalline and polycrystalline silicon.

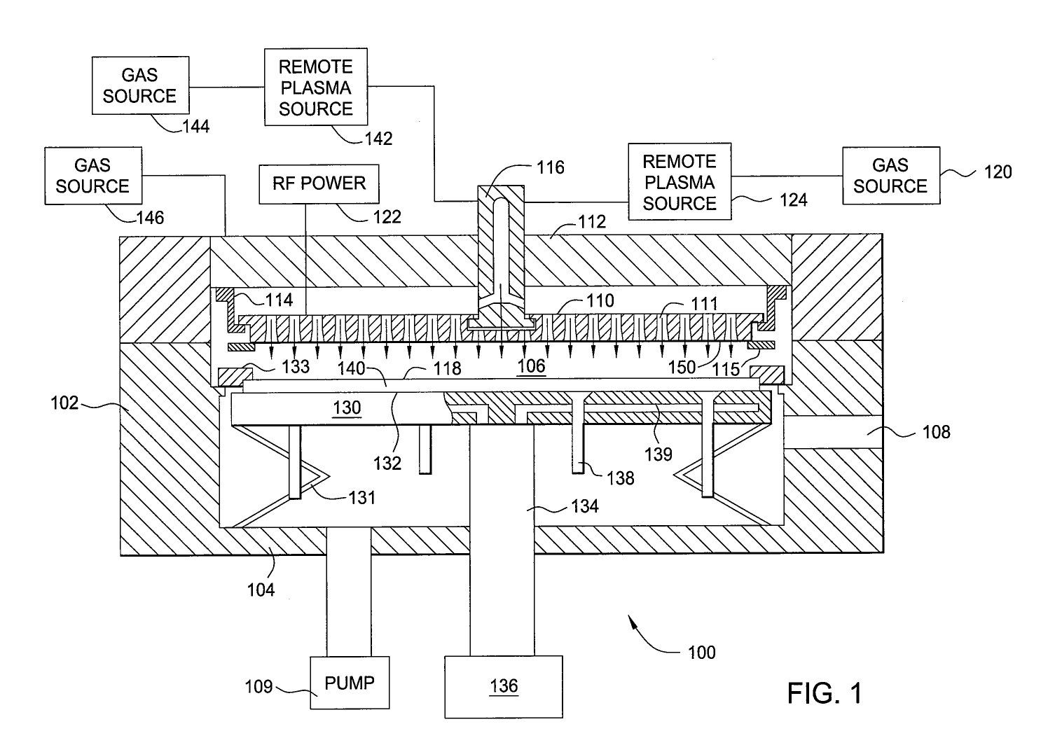

FIG. 1 depicts a schematic cross-section view of one embodiment of a plasma enhanced chemical vapor deposition (PECVD) chamber 100 having a remote hydrogen plasma source. The remote hydrogen plasma source may assist providing atomic hydrogen sources into the processing chamber 100 for depositing a silicon layer with low defect density. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 100 generally includes walls 102, a bottom 104, and a showerhead 110, and a substrate support 130 which define a process volume 106. The process volume 106 is accessed through a valve 108, such that the substrate 140, may be transferred in and out of the chamber 100. In one embodiment, the substrate 140 having a plain surface area of 10,000 cm² or more, 40,000 cm² or more, or 55,000 cm² or more is disposing in the chamber 100. It is understood that after processing the substrate 140 may be cut to form smaller solar cells. The substrate support 130 includes a substrate receiving surface 132 for supporting the substrate 140. A stem 134 coupled to a lift system 136 to raise and lower the substrate support 130. A shadow ring 133 may be optionally placed over periphery of the substrate 140. Lift pins 138 are moveably disposed through the substrate support 130 to move a substrate 140 to and from the substrate receiving surface 132. The substrate support 130 may also include heating and/or cooling elements 139 to maintain the substrate support 130 at a desired temperature. In one embodiment, the heating and/or cooling elements 139 may be set to provide a substrate support temperature during deposition of about 400° C. or less, such as between about 100° C. and about 400° C., for example between about 150° C. and about 300° C., or such as about 200° C. In one embodiment, the a substrate support temperature during deposition is about 170° C. and about 190° C. when depositing mc-Si and about 200° C. and about 210° C. when depositing a-Si. The substrate support 130 may also include grounding straps 131 to provide RF grounding at the periphery of the substrate support 130.

The showerhead 110 is coupled to a backing plate 112 at its periphery by a suspension 114. The showerhead 110 may also be coupled to the backing plate 112 by one or more center supports 116 to help prevent sag and/or control the straightness/curvature of the showerhead 110. A first gas source 146 is coupled to the backing plate 112 to provide gas through the backing plate 112 and through the showerhead 110 toward the substrate receiving surface 132. Alternatively, the first gas source 146 may be coupled to the center support 116 to supply gas therefrom to the processing volume 106. A second gas source 120 may be coupled to the backing plate 112 through a first remote plasma source 124. The first remote plasma source 124, such as an inductively coupled remote plasma source, is coupled between the gas source 120 and the backing plate 112 to plasma dissociate the gases supplied from the gas source 120. The dissociated plasma species are then delivered to the process volume 106. The gases supplied from the second gas source 120 may be cleaning gas, processing gas, or any other gases that may be used to assist deposition process in the process volume 106 or cleaning the chamber after substrate processing.

Optionally, a third gas source 144 may be coupled to the backing plate 112 through a second remote plasma source 142. In this configuration, the first remote plasma source 124 and the second remote plasma source 142 may be utilized to each dissociate different types of the gas respectively supplied from the second gas source 120 and the third gas source 144. In one embodiment, the first remote plasma source 124 may be configured to plasma dissociate a cleaning gas supplied from the second gas source 120 between substrates processing so that a remote plasma is generated and provided to clean chamber components. The cleaning gas may be further excited by RF power provided to the showerhead 110 from RF plasma source 122. The second remote plasma source 142 may be configured to plasma dissociate a processing gas supplied from the third gas source 144 so that a remote plasma dissociated reacting species may be provided and delivered to the processing volume 106 during processing. The individual generation of the remote cleaning source and remote reacting species from the first and the second remote plasma source 124, 142 can prevent cross contamination of the cleaning gas species and the processing gas species. In the embodiment wherein the second remote plasma source 142 and the third gas source 144 are not present, the remote cleaning gas and the remote processing gas may be generated and plasma dissociated in the same remote plasma source, if needed. It is noted that the gas arrangement or configuration among the first remote plasma source 124, the second remote plasma source 142, the second gas source 120 and the third gas source 144 may be arranged in any order or in any configuration as needed.

In one embodiment, suitable cleaning gases include, but are not limited to, NF₃, F₂, and SF₆. Suitable reacting gases include, but are not limited to, H₂, O₂, H₂O, or inert gas, such as He and Ar. Other suitable cleaning gases include NF₃ and Ar; He with F₂ or SF₆; O₂ and He; and O₂, He and Ar. In an exemplary embodiment, the cleaning gas supplied to the first remote plasma source 124 and further to the processing volume 106 is NF₃ and the reacting gas supplied to the second remote plasma source 142 and further to the processing volume 106 is H₂.

A vacuum pump 109 is coupled to the chamber 100 to control the process volume 106 at a desired pressure. The RF power source 122 is coupled to the backing plate 112 and/or to the showerhead 110 to provide RF power to the showerhead 110 so that an electric field is created between the showerhead 110 and the substrate support 130 so that a plasma may be generated from the gases present between the showerhead 110 and the substrate support 130. Various RF frequencies may be used, such as a frequency between about 0.3 MHz and about 200 MHz. In one embodiment the RF power is provided to the showerhead 110 at a frequency of 13.56 MHz.

The spacing during deposition between the top surface of a substrate 102 disposed on the substrate receiving surface 132 and the showerhead 610 may be between 400 mil and about 1,200 mil, such as between 400 mil and about 800 mil.

During processing, processing gases may be supplied from the first gas source 146 through the showerhead 110 to the processing volume 106. In addition, processing gases may also be delivered through the remote plasma source 124, 142 and remotely dissociated by the remote plasma source 124, 142 to the processing volume 106. In one embodiment, the processing gas supplied from the first gas source 146 is silane gas and the processing gas supplied from on or both of the second or third gas source 120, 144 is hydrogen gas and/or other dopant gases if necessary. The hydrogen gas and/or other dopant gases are remotely plasma dissociated in the first or second remote plasma source 124, 144 to provide a remote source of atomic hydrogen and/or other dopant gases to the processing volume 106. It is believed that remotely dissociated hydrogen gas and/or other dopant gases can provide more atomic hydrogen or other types of active species, which may reactively and efficiently react with the silane species supplied to the processing volume 106, thereby providing a more complete deposition reaction and reducing dangling bond formation during processing. It is believed that atomic hydrogen has higher degree of reactivity, which may react with dissociated silane species more efficiently and thoroughly. Different dopant gases or other gases that may also be supplied from the first gas source 146 to the processing volume 106 to form doped silicon containing layer, or other desired films.

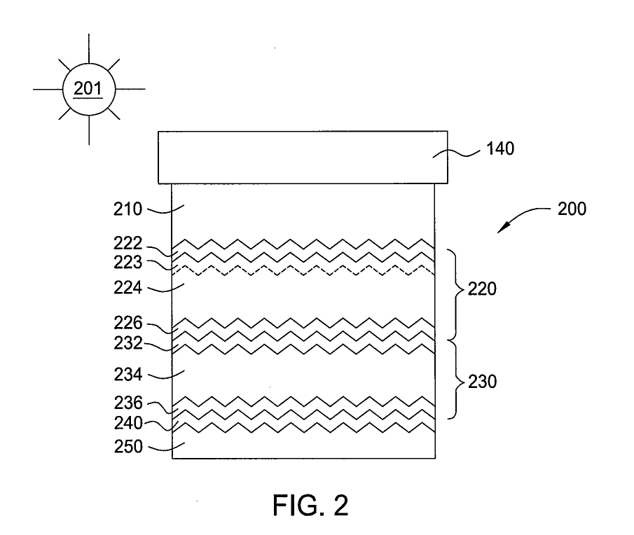

FIG. 2 is a schematic diagram of an embodiment of a multi-junction solar cell 200 oriented toward a light or solar radiation 201. The solar cell 200 is formed on the substrate 140. A first transparent conducting oxide (TCO) layer 210 formed over the substrate 140, a first p-i-n junction 220 formed over the first TCO layer 210. A second p-i-n junction 230 formed over the first p-i-n junction 220, a second TCO layer 240 formed over the second p-i-n junction 230, and a metal back layer 250 formed over the second TCO layer 240. The substrate 140 may be a glass substrate, polymer substrate, metal substrate, or other suitable substrate, with thin films formed thereover.

The first TCO layer 210 and the second TCO layer 240 may each comprise tin oxide, zinc oxide, indium tin oxide, cadmium stannate, combinations thereof, or other suitable materials. It is understood that the TCO materials may also additionally include dopants and components. For example, zinc oxide may further include dopants, such as tin, aluminum, gallium, boron, and other suitable dopants. Zinc oxide, in one embodiment, comprises 5 atomic % or less of dopants, and more preferably comprises 2.5 atomic % or less aluminum. In certain instances, the substrate 140 may be provided by the glass manufacturers with the first TCO layer 210 already deposited thereon.

To improve light absorption by enhancing light trapping, the substrate 140 and/or one or more of thin films formed thereover may be optionally textured by wet, plasma, ion, and/or other mechanical processes. For example, in the embodiment shown in FIG. 2, the first TCO layer 210 is sufficiently textured so that the topography of the surface is substantially transferred to the subsequent thin films deposited thereover.

The first p-i-n junction 220 may comprise a p-type silicon containing layer 222, an optional p-l buffer intrinsic type silicon containing layer (PIB layer) 223, an intrinsic type silicon containing layer 224 formed over the PIB layer 223, and an n-type silicon containing layer 226 formed over the intrinsic type silicon containing layer 224. In certain embodiments, the p-type silicon containing layer is a p-type amorphous silicon layer 222 having a thickness between about 60 Å and about 300 Å, for example about 80 Å. The PIB layer is an intrinsic type amorphous silicon layer 223 having a thickness between about 0 Å and about 500 Å, for example about 100 Å. In certain embodiments, the intrinsic type silicon containing layer 224 is an intrinsic type amorphous silicon layer having a thickness between about 1,500 Å and about 3,500 Å. In certain embodiments, the n-type silicon containing layer is a n-type microcrystalline silicon layer 226 may be formed to a thickness between about 100 Å and about 400 Å. In other embodiments, there is amorphous N-type layer having a thickness of between 0 Å and 500 Å under the n-type silicon containing layer 226, so the structure is a-P/a-PIB/al/a-N/mc-N where a is amorphous, mc is microcrystalline and l is intrinsic layer.

The second p-i-n junction 230 may comprise a p-type silicon containing layer 232 and an intrinsic type silicon containing layer 234 formed over the p-type silicon containing layer 232, and a n-type silicon containing layer 236 formed over the intrinsic type silicon containing layer 234. In certain embodiments, the p-type silicon containing layer 232 may be a p-type microcrystalline silicon layer 232 having a thickness between about 100 Å and about 400 Å. In certain embodiments, the intrinsic type silicon containing layer 234 is an intrinsic type microcrystalline silicon layer having a thickness between about 10,000 Å and about 30,000 Å. In certain embodiments, the n-type silicon containing layer 236 is an amorphous silicon layer having a thickness between about 100 Å and about 500 Å.

The metal back layer 250 may include, but not limited to a material selected from the group consisting of Al, Ag, Ti, Cr, Au, Cu, Pt, alloys thereof, and combinations thereof. Other processes may be performed to form the solar cell 200, such a laser scribing processes. Other films, materials, substrates, and/or packaging may be provided over metal back layer 250 to complete the solar cell device. The formed solar cells may be interconnected to form modules, which in turn can be connected to form arrays.

Solar radiation 201 is primarily absorbed by the intrinsic layers 224, 234 of the p-i-n junctions 220, 230 and is converted to electron-holes pairs. The electric field created between the p-type layer 222, 232 and the n-type layer 226, 236 that stretches across the intrinsic layer 224, 234 and causes electrons to flow toward the n-type layers 226, 236 and holes to flow toward the p-type layers 222, 232 creating a current. The first p-i-n junction 220 may comprise an intrinsic type amorphous silicon layer 224 and the second p-i-n junction 230 may comprise an intrinsic type microcrystalline silicon layer 234 to take advantage of the properties of amorphous silicon and microcrystalline silicon which absorb different wavelengths of the solar radiation 201. Therefore, the formed solar cell 200 is more efficient, as it captures a larger portion of the solar radiation spectrum. The intrinsic layer 224 of amorphous silicon and the intrinsic layer 234 of microcrystalline are stacked in such a way that solar radiation 201 first strikes the intrinsic type amorphous silicon layer 224 and then strikes the intrinsic type microcrystalline silicon layer 234, since amorphous silicon has a larger bandgap than microcrystalline silicon. Solar radiation not absorbed by the first p-i-n junction 220 is transmitted to the second p-i-n junction 230.

It is noted that all the p-type layers 222, 232, n-type layers 226, 236, intrinsic type layers 224, 234 and PIB layer 223 may all be manufactured by a PECVD chamber, such as the chamber 100, as depicted in FIG. 1. Below are examples and process parameters that may be used to form all different types of the semiconductor layers that may be used to form solar cell, such as solar cell 200 of FIG. 2, using the PECVD chamber 100 of FIG. 1 or other suitable chambers.

In an embodiment wherein the intrinsic silicon containing layer 224 is an intrinsic amorphous silicon layer, the intrinsic amorphous silicon layer 224 may be deposited by providing a gas mixture of hydrogen gas to silane gas in a flow rate ratio by volume of about 20:1 or less. Silane gas may be provided at a flow rate between about 0.5 sccm/L and about 7 sccm/L, such as 3.1 sccm/L. Hydrogen gas may be provided from a remote plasma source at a flow rate between about 5 sccm/L and 60 sccm/L, such as 31 sccm/L. An RF power between 15 mW/cm² and about 250 mW/cm² may be provided to the showerhead, such as 50 to 60 15 mW/cm². When using remote source for H₂, lower power such as little as 5 mW/cm² may be utilized. The pressure of the chamber may be maintained between about 0.1 Torr and 20 Torr, such as between about 0.5 Torr and about 5 Torr, such as 2.5 Torr. The deposition rate of the intrinsic type amorphous silicon layer 224 will be about 100 Å/min or more, for example about 270 Å/min. In an exemplary embodiment, the intrinsic type amorphous silicon layer 108 is deposited at a hydrogen to silane flow rate ratio by volume at about 12.5:1.

In an embodiment wherein the intrinsic type silicon containing layer 234 is an intrinsic type microcrystalline silicon layer, the intrinsic type microcrystalline silicon layer 234 may be deposited by providing a gas mixture of silane gas and hydrogen gas in a flow rate ratio by volume of hydrogen to silane between about 20:1 and about 2000:1. Silane gas may be provided at a flow rate between about 0.5 sccm/L and about 5 sccm/L. Hydrogen gas may be provided from a remote plasma source at a flow rate between about 20 sccm/L and about 4000 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. Applying RF power between about 5 mW/cm² to 1600 mW/cm² or greater, such as 490 mW/cm² or greater, at a chamber pressure between about 1 Torr and about 100 Torr, such as between about 3 Torr and about 20 Torr, or between about 4 Torr and about 12 Torr, will generally deposit an intrinsic type microcrystalline silicon layer having crystalline fraction between about 20 percent and about 80 percent, such as between 55 percent and about 75 percent, at a rate of about 200 Å/min or more, such as about 400 Å/min or more. In some embodiments, it may be advantageous to ramp the power density of the applied RF power from a first power density to a second power density during deposition. In one embodiment, 0.8 sccm/L of SiH₄ may be provide with 75.6 sccm/L of H₂ provided through the remove plasma source, source power to the showerhead is about 489.5 mW/sq cm while the pressure is maintained about 9 Torr to obtain a deposition rate of about 380 Å/min.

In another embodiment, the intrinsic type microcrystalline silicon layer 234 may be deposited using multiple steps, wherein the portion of the layer deposited during each step has a different hydrogen dilution ratio that can provide different crystal fraction of the deposited films. In one embodiment, for example, the flow rate ratio by volume of hydrogen to silane may be reduced in four steps from 100:1 to 95:1 to 90:1 and then to 85:1. In one embodiment, silane gas may be provided at a flow rate between about 0.1 sccm/L and about 5 sccm/L, such as about 0.97 sccm/L. Hydrogen gas may be provided from a remote plasma source at a flow rate between about 10 sccm/L and about 200 sccm/L, such as between about 40 sccm/L and about 105 sccm/L. In an exemplary embodiment wherein the deposition process has multiple steps, such as four steps, hydrogen gas flow may start at about 76 sccm/L during the first step, and be gradually reduced to about 72 sccm/L, 68 sccm/L, and 64.5 sccm/L respectively in the subsequent process steps. Applying RF power between about 300 mW/cm² or greater, such as about 490 mW/cm² at a chamber pressure between about 1 Torr and about 100 Torr, for example between about 3 Torr and about 20 Torr, such as between about 4 Torr and about 12 Torr, such as about 9 Torr, will result in deposition of an intrinsic type microcrystalline silicon layer at a rate of about 200 Å/min or more, such as 400 Å/min.

In one embodiment, the p-i buffer intrinsic type amorphous silicon layer (PIB layer) 223 may be deposited by providing a gas mixture of hydrogen gas to silane gas in a ratio of about 40:1 or less, for example, less than about 30:1, for example between about 20:1 and about 30:1, such as about 25. Silane gas may be provided at a flow rate between about 0.5 sccm/L and about 5 sccm/L, such as about 2.28 sccm/L. Hydrogen gas may be provided at a flow rate between about 5 sccm/L and 80 sccm/L, such as between about 20 sccm/L and about 65 sccm/L, for example about 57 sccm/L. An RF power between 15 milliWatts/cm² and about 250 milliWatts/cm², such as between about 30 milliWatts/cm² may be provided to the showerhead. The pressure of the chamber may be maintained between about 0.1 Torr and 20 Torr, preferably between about 0.5 Torr and about 5 Torr, such as about 3 Torr. The deposition rate of the p-i buffer intrinsic type amorphous silicon layer (PIB layer) may be about 100 Å/min or more. The thickness of the p-i buffer intrinsic type amorphous silicon layer (PIB layer) is about 0 Å and about 500 Å, such as about 0 Å and about 200 Å, for example, about 100 Å. It is noted that the p-i buffer intrinsic type amorphous silicon layer (PIB layer) 223 and the bulk intrinsic type amorphous silicon layer 224 may be integratedly deposited in a single chamber or individually deposited at separate chambers.

Charge collection is generally provided by doped semiconductor layers, such as silicon layers doped with p-type or n-type dopants. P-type dopants are generally Group III elements, such as boron or aluminum. N-type dopants are generally Group V elements, such as phosphorus, arsenic, or antimony. In most embodiments, boron is used as the p-type dopant and phosphorus as the n-type dopant. These dopants may be added to the p-type and n-type layers 222, 226, 232, 236 described above by including boron-containing or phosphorus-containing compounds in the reaction mixture. The dopant gas may be supplied from the first gas source 146 of processing chamber 100, as depicted in FIG. 1. Alternatively, the dopant gas may be supplied from the second and the third gas source 120, 144 through the first and the second remote plasma source 124, 142 as needed. Examples of dopant gas include boron containing gas and phosphorous gas. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is the most common phosphorus compound. The dopants are generally provided with a carrier gas, such as hydrogen, helium, argon, or other suitable gas. If hydrogen is used as the carrier gas, the total hydrogen in the reaction mixture is increased. Thus, the hydrogen ratios discussed above will include the portion of hydrogen contributed carrier gas used to deliver the dopants.

Dopants will generally be provided as dilutants in an inert gas or carrier gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm³ and about 10²⁰ atoms/cm³.

In one embodiment wherein the p-type silicon containing layer 232 is a p-type microcrystalline silicon layer, the p-type microcrystalline silicon layer 232 may be deposited by providing a gas mixture of hydrogen gas and silane gas in flow rate ratio by volume of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided from a remote plasma source at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. Applying RF power between about 50 mW/cm² and about 700 mW/cm², such as between about 290 mW/cm² and about 440 mW/cm², at a chamber pressure between about 1 Torr and about 100 Torr, such as between about 3 Torr and about 20 Torr, between 4 Torr and about 12 Torr, or about 7 Torr or about 9 Torr, will deposit a p-type microcrystalline layer having crystalline fraction between about 20 percent and about 80 percent, such as between 50 percent and about 70 percent for a microcrystalline layer, at about 10 Å/min or more, such as about 234 Å/min or more.

In one embodiment wherein the p-type silicon containing layer 222 is a p-type amorphous silicon layer, the p-type amorphous silicon layer 222 may be deposited by providing a gas mixture of hydrogen gas to silane gas in a flow rate ratio by volume of about 20:1 or less. Silane gas may be provided at a flow rate between about 1 sccm/L and about 10 sccm/L. Hydrogen gas may be provided from a remote plasma source at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. Applying RF power between about 15 mWatts/cm² and about 200 mWatts/cm² at a chamber pressure between about 0.1 Torr and 20 Torr, such as between about 1 Torr and about 4 Torr, will deposit a p-type amorphous silicon layer at about 100 Å/min or more. The addition of methane or other carbon containing compounds, such as CH₄, C₃H₈, C₄H₁₀, or C₂H₂, can be used to form a carbon containing p-type amorphous silicon layer 106 that absorbs less light than other silicon containing materials. In other words, in the configuration where the formed p-type amorphous silicon layer 222 contains alloying elements, such as carbon, the formed layer will have improved light transmission properties, or window properties (e.g., to lower absorption of solar radiation). The increase in the amount of solar radiation transmitted through the p-type amorphous silicon layer 222 can be absorbed by the intrinsic layers, thus improving the efficiency of the solar cell. In the embodiment wherein trimethylboron is used to provide boron dopants in the p-type amorphous silicon layer 222, the boron dopant concentration is maintained at between about 1×10¹⁸ atoms/cm² and about 1×10²⁰ atoms/cm². In an embodiment wherein methane gas is added and used to form a carbon containing p-type amorphous silicon layer, a carbon concentration in the carbon containing p-type amorphous silicon layer is controlled to between about 10 atomic percent and about 20 atomic percent. In one embodiment, the p-type amorphous silicon layer 222 has a thickness between about 20 Å and about 300 Å, such as between about 80 Å and about 200 Å while depositing at about 307 Å/min.

In one embodiment wherein the n-type silicon containing layer 236 is a n-type microcrystalline silicon layer, the n-type microcrystalline silicon layer 236 (one layer after the p-type silicon containing layers 232 and before the intrinsic type silicon containing layers 234 are not shown in FIG. 2) may be deposited by providing a gas mixture of hydrogen gas to silane gas in a flow rate ratio by volume of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided from the remote plasma source at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. Applying RF power between about 100 mW/cm² and about 900 mW/cm², such as about 370 mW/cm², at a chamber pressure of between about 1 Torr and about 100 Torr, such as between about 3 Torr and about 20 Torr, or between 4 Torr and about 12 Torr, for example about 6 Torr or about 9 Torr, will deposit an n-type microcrystalline silicon layer having a crystalline fraction between about 20 percent and about 80 percent, such as between 50 percent and about 70 percent, at a rate of about 50 Å/min or more, such as about 196 Å/min or more.

In one embodiment wherein the n-type silicon containing layer 236 is a n-type amorphous silicon layer, the n-type amorphous silicon layer 236 may be deposited by providing a gas mixture of hydrogen gas to silane gas in a flow rate ratio by volume of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided from a remote plasma source at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. Applying RF power between about 25 mW/cm² and about 250 mW/cm², such as about 60 mW/cm² or about 80 mW/cm², at a chamber pressure between about 0.1 Torr and about 20 Torr, such as between about 0.5 Torr and about 4 Torr, or about 1.5 Torr, will deposit an n-type amorphous silicon layer at a rate of about 100 Å/min or more, such as about 200 Å/min or more, such as about 300 Å/min or about 600 Å/min.

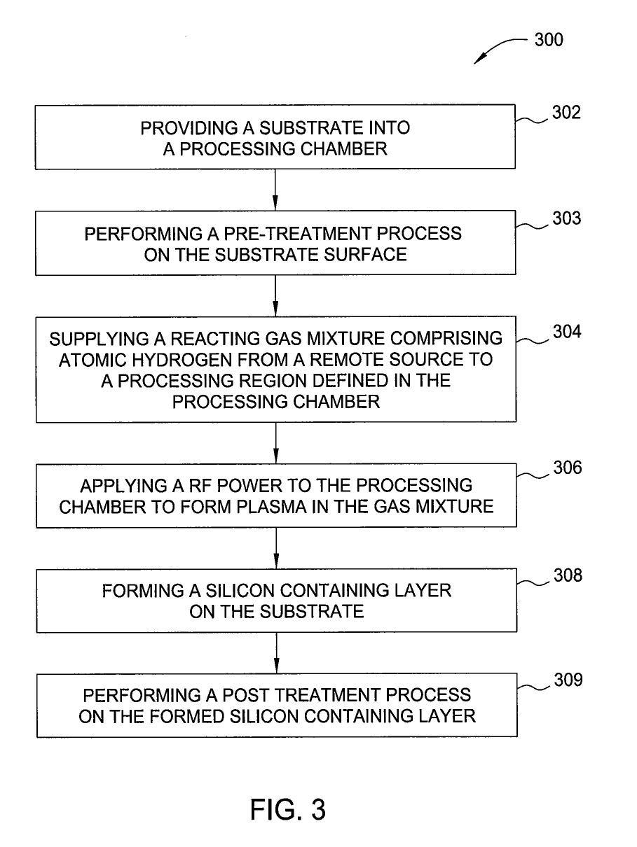

FIG. 3 depicts a flow diagram of one embodiment of a deposition process 300 that may be practiced in the chamber 100, as described in FIG. 1, or other suitable plasma processing chamber. The process 300 illustrates a method of depositing a silicon containing layer that may be used in TFT devices, diode devices or solar cell devices (such as the solar cell 200 depicted in FIG. 2). In one embodiment, the process 300 provides atomic hydrogen from a remote plasma source that can assist reaction with silane to form silicon containing layers during deposition. Furthermore, the process 300 may also provide atomic hydrogen that can facilitate performing a pretreatment process on the substrate prior to the deposition process and a post treatment process after the deposition process. The atomic hydrogen from remote plasma source may be supplied to the processing chamber by a separate channel or the same channel where other processing gases are supplied.

The process 300 begins at step 302 by providing the substrate 140 in a process chamber, such as the process chamber 100 depicted in FIG. 1. The substrate 140 may have a first TCO layer 210 formed on the substrate 140. Alternatively, the substrate 140 may have different combination of films, structures or layers previously formed thereon to facilitate forming different solar device structures on the substrate 140. In one embodiment, the substrate 140 may be any one of glass substrate, plastic substrate, polymer substrate, metal substrate, singled substrate, or other suitable transparent substrate suitable for forming solar cell devices thereon. In one embodiment, the process 300 may be performed to form the p-type silicon containing layers 222, 232, PIB layer 223, intrinsic type silicon containing layers 224, 234, and n-type silicon containing layer 226, 236, as depicted in FIG. 2 or any other suitable silicon containing layer.

At step 303, an optional pretreatment process may be performed to treat the substrate surface. It is noted that the materials of the substrate surface to be treated may vary based on the different film layers previously formed on the substrate 140. For example, in the embodiment wherein the substrate 140 includes the TCO layer 210 and the p-type silicon containing layer 222 previously formed thereon, the pretreatment process may be performed on the p-type silicon containing layer 222. Alternatively, the pretreatment process may be performed on any layers that may be utilized to form solar cell devices including the TCO layers 210, 240, p-type silicon containing layers 222, 232, PIB layer 223, i-type silicon containing layer 224, 234, and n-type silicon containing layers 226, 236 and other suitable film layers. In an exemplary embodiment, the pretreatment process is performed on the surface of the p-type silicon containing layers 222, 232 prior to the deposition of i-type silicon containing layers 224, 234. In yet another exemplary embodiment, the pretreatment process is performed on the surface of the PIB layer 223 prior to the deposition of i-type silicon containing layer 224.

In one embodiment, the pretreatment process is performed by supplying a pretreatment gas mixture into the processing chamber. The pretreatment gas mixture may be selected from a group consisting of hydrogen, H₂O gas, nitrogen gas, N₂O, NO₂, argon gas, helium gas and other suitable gases. Pre-treatment gases used for solar applications may include H₂, Ar, He or mixture of these gases. In one exemplary embodiment, the pretreatment gas mixture supplied into the processing chamber for performing the pretreatment process includes a hydrogen gas. In one embodiment, a plasma formed from the pretreatment gas mixture is ignited by applying about 10,000 or more watts RF to the shower head.

In one embodiment, the pretreatment gas mixture may be supplied from a remote plasma source, such as the remote plasma source 124, 144 coupled to the process chamber. It is believed that the pretreatment gas mixture supplied from a remote source may provide a relatively gentle treatment process that will slightly and gently treat the surface of the substrate 140 without damage the substrate surface or the film layers disposed on the substrate 140. The pretreatment process may assist removing surface contaminant, native oxide, particles and other undesired materials from the substrate surface. By supplying the pretreatment gas mixture from a remote source, the surface contaminant, native oxide, particles and other undesired materials may be efficiently removed without damaging the underlying substrate surface. Furthermore, the pretreatment process is also believed to improve electrical properties at the interface as the surface defects may be removed or eliminated during the treatment process. Atomic hydrogen is believed to heal the defects formed at the interface of the film layer being treated.

In one embodiment, the plasma pretreatment process may be performed by supplying the pretreatment gas mixture, such as a hydrogen gas, helium, or argon gas or combinations thereof, into the processing chamber. The gas flow for supplying the pretreatment gas mixture is between about 0.15 sccm/L and about 60 sccm/L, such as between about 1 sccm/L and about 2 sccm/L. In the embodiment wherein the pretreatment gas mixture utilizes hydrogen gas as the pretreatment gas, the hydrogen gas may be supplied at about 0.15 sccm/L and about 60 sccm/L, such as about 1 sccm/L. The RF power supplied from the remote plasma source to do the pretreatment process may be controlled at between about 15 milliWatts/cm² and about 300 milliWatts/cm², such as about 15 milliWatts/cm², may be provided to the showerhead, for example between about 300 milliWatts/cm² and about 35 milliWatts/cm², such as about 70 milliWatts/cm² for pretreatment treatment and about 70 milliWatts/cm² for argon treatment. The process pressure may be controlled at between about 0.5 Torr and about 20 Torr.

At step 304, a reacting gas mixture is supplied into the processing chamber 100 to deposit a silicon containing layer on the substrate 140. In an exemplary embodiment, the silicon containing layer formed on the substrate 140 is an intrinsic type silicon containing layer 224, 234, as depicted in FIG. 2. The reacting gas mixture supplied to the processing chamber may include a silicon-based gas and a hydrogen based gas from a remote plasma source, such as the remote plasma source 124, 142, as depicted in FIG. 1. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. In one embodiment, the silicon-based gas described here is silane (SiH₄) gas. Suitable hydrogen-based gases include, but are not limited to, hydrogen gas (H₂).

In one embodiment, the silicon based gas is silane (SiH₄) and the hydrogen-based gas is hydrogen (H₂). The silane gas and the hydrogen gas are supplied at a predetermined gas flow ratio. The predetermined gas flow ratio of hydrogen to silane gas assists the silicon containing layer formed with a desired crystalline fraction (e.g., if the silicon containing layer is configured to form as a microcrystalline or polycrystalline silicon layer) and grain structure. In one embodiment, the hydrogen to silane gas flow ratio (e.g., flow volume ratio) in the reacting gas mixture is controlled at greater than 200:1, for example, greater than 500:1, such as between about 500:1 and about 3000:1, or between about 1000:1 and about 2500:1, such as about 2000:1. During deposition, hydrogen gas supplied from the remote source 124, 142 may be remotely dissociated and react with the silane radicals dissociated in the processing volume 106, as depicted in FIG. 1. The atomic hydrogen from the remote source reacts with the dangling bonds and silicon or hydrogen free radicals dissociated from the silane gas. The reaction of the atomic hydrogen with the silicon and hydrogen radicals dissociated from silane gas drives out the weak and dangling bonds of the silicon-hydrogen bonding or strained amorphous silicon-silicon bonding in the deposited silicon film, thereby leaving silicon atoms in the film to form strong silicon-silicon bonding. Strong silicon-silicon bonding promotes purity and high silicon bonding energy in the resultant film, thereby increasing the grain structure and reducing defect density. It is believed that the atomic hydrogen from remote plasma source readily dissociates silane gas and thereby produces the required silane precursor the formation of device quality of intrinsic layer.

As the hydrogen gas is remotely dissociated in a remote plasma source, instead of dissociated in the processing volume in the processing chamber as conventionally practiced in the art, the hydrogen gas may be dissociated more effectively and thoroughly, thereby providing a greater amount of effective atomic hydrogen to the processing volume 106. In conventional practice where the hydrogen gas is supplied and dissociated in the processing chamber, the dissociated atomic hydrogen is often recombined or prematurely reacts with other species (e.g., silicon ions or radicals, hydrogen ions or radicals dissociated from silane) present in the processing volume 106, thereby resulting in dangling bonds being formed in the resultant film, creating an undesired film defect. Furthermore, the higher amount of atomic hydrogen also provides and forms a hydrogen rich surface which may prevent subsequently dissociated hydrogen radicals from the silane gas from being reattached into the silicon. Therefore, by dissociating hydrogen gas from a remote source, the hydrogen gas may be more efficiently dissociated into atomic hydrogen and subsequently delivered to the processing volume to react with other dissociated species formed therein, thereby providing an efficient deposition process with high film density and low defects. It is believed that as the H₂ is remotely dissociated using remote plasma source, the film damage due to plasma bombardment is reduced, thereby the dangling bond formation associated to plasma bombardment is reduced. This resultant yield in device quality formation.

In one embodiment wherein the substrate has a substrate size about 2200 mm×2600 mm, the SiH₄ gas may be supplied at a flow rate between about 1450 sccm and 14500 sccm, such as between about 2000 and about 3000 sccm, into the processing chamber. H₂ gas may be supplied from a remote plasma source at a flow rate at between about 58000 sccm and about 11600000 sccm, such as between about 60000 sccm and about 120000 sccm, into the processing chamber. An inert gas, such as Ar or helium gas, may be supplied in the reacting gas mixture to assist carrying and diluting the gas species in the reacting gas mixture. In one embodiment, the inert gas may be supplied in the reacting gas mixture at a flow rate of less than about 20000 sccm, such as about 5000 sccm.

At step 306, during deposition, a RF power may be supplied to the processing chamber to form plasma in the reacting gas mixture supplied to the processing chamber. As discussed above, as the hydrogen gas may be remotely dissociated at a remote plasma source, a relatively lower RF power, such as less than about 17.5 mWatts/cm², may be applied to the processing chamber. As the hydrogen gas has been remotely dissociated, the RF power applied to the processing chamber only need to dissociate silane gas, or inert gas, if any, supplied to the processing chamber. Accordingly, a relatively lower RF power supplied into the processing chamber reduces the likelihood of damage to the substrate or the film formed on the substrate. Furthermore, a relatively lower RF power applied to the processing chamber may also reduce the likelihood of damage to the chamber components and parts.

In one embodiment, the RF power supplied to the processing chamber may be controlled between about 1000000 milliWatts (17.5 mWatts/cm²) and about 80000000 milliWatts (1400 mWatts/cm²), such as between about 26000000 milliWatts (455 mWatts/cm²) and about 28000000 milliWatts (4900 mWatts/cm²). The RF power may be applied to the processing chamber may also be controlled by RF power density less than about 5 mWatt/cm², such as between about 1600 mWatt/cm² and about 490 mWatt/cm². The RF power is provided between about 100 kHz and about 100 MHz, such as about 350 kHz or about 13.56 MHz. Alternatively, a VHF power may be utilized to provide a frequency up to between about 27 MHz and about 200 MHz. The processing pressure may be controlled between about 0.5 Torr and about 20 Torr, such as between about 6 Torr and about 9 Torr. The spacing of the substrate to the gas distribution plate assembly may be controlled in accordance with the substrate dimension. In one embodiment, the processing spacing for a substrate greater than 1 square meters is controlled between about 400 mils and about 1200 mils, for example, between about 400 mils and about 850 mils, such as between about 580 mils and 810 mils. The substrate temperature may be controlled at between about 150 degrees Celsius and about 500 degrees Celsius, such as between about 200 to about 370 degrees Celsius.

At step 308, after the RF power and reacting gas mixture is supplied to the processing chamber, a silicon containing layer may be formed on the substrate. It is noted that if the silicon containing layer is configured to be formed as doped semiconductor layer, such as the p-type or n-type layers 222, 232, 226, 236, the dopant gas may be supplied with the reacting gas mixture from the first gas source 146 to the processing volume 106, as depicted in FIG. 1. The gases supplied form the first gas source 146 may share the same channel or have different channel from the gases supplied from the first or the second remote power source 124, 142 to the processing volume as needed.

At step 309, after the desired film layer is formed on the substrate 104, an optional post treatment process may be performed on the deposited material layer on the substrate surface. It is noted that the materials of the substrate surface to be post treated may vary based on the film layers previously formed on the substrate 140. For example, in the embodiment wherein the silicon containing formed at step 308 is configured to be the intrinsic type silicon containing layer 224, 234, the post treatment process may be performed on the formed intrinsic type silicon containing layer 224, 234. Alternatively, the post treatment process may be performed on any layers that may be utilized to form solar cell devices including the TCO layers 210, 240, p-type silicon containing layers 222, 232, PIB layer 223, i-type silicon containing layer 224, 234, and n-type silicon containing layers 226, 236 and other suitable film layers. In an exemplary embodiment, the post treatment process is performed on the surface of the intrinsic type silicon containing layer 224, 234 prior to the deposition of n-type silicon containing layers 226, 236. In yet another exemplary embodiment, the post treatment process is performed on the surface of the PIB layer 223 prior to the deposition of i-type silicon containing layer 224.

It is believed that post treatment process may assist densifying the formed layer on the substrate surface, thereby improving the film and electrical properties of the layers formed on the substrate. In one exemplary embodiment, the post treatment process may be performed by supplying a post treatment gas mixture to treat the film layer formed on the substrate surface. In the embodiment wherein the post treatment gas mixture includes a hydrogen gas, it is believed that plasma dissociated hydrogen atoms may assist driving out the weak and dangling bond of the silicon-hydrogen bonding or strained amorphous silicon-silicon bonding in the silicon film, thereby leaving silicon atoms in the film to form strong silicon-silicon bonding. Strong silicon and silicon bonding promotes purity and silicon bonding energy formed in the resultant film, thereby increasing the crystalline fraction and crystal structure formed in the microcrystalline film.

Furthermore, it is also believed that the post treatment process may also alert the stress of the treated film layer. The stress of the film layer may be alerted by adjusting the RF plasma power, process pressure, and gas flow ratio supplied during the post treatment process at step 309, thereby densifying and purifying the film layer formed on the substrate. In one embodiment, the stress of the film layer formed on the substrate 140 may become more compressive after the post treatment process is performed on the film layer. It is found that the higher the RF power is utilized during the post treatment process and a more compressive film may be obtained after the post treatment process. As the dangling bond may be driven out during the post treatment process, the distance between each atoms formed in the treated film may become shorter and the overall film density may be become higher and more compact, thereby resulting the deposited film as a more compressive film. Additionally, as the film stress is increased, the bonding in the film structure may become stronger and more robust. The internal stress of the film is a good measure of density of the film. With the internal stress becoming more and more compressive indicates the film is getting denser. With post treatment it is seen that film stress can become very compressive depicting that the film grown is densified. Also, it is believed that the post treatment process supplies enough energy to relax dangling bond thereby improving the device quality of the film.

In one embodiment, the post plasma treatment process at step 309 may be performed by supplying the post treatment gas mixture. The post treatment gas mixture may be selected from a group consisting of hydrogen, H₂O gas, nitrogen gas, N₂O, NO₂, argon gas, helium gas, combinations thereof and other suitable gases. The post treatment gases used for solar applications may include H₂, Ar, He or mixture of these gases. In one exemplary embodiment, the post treatment gas mixture supplied into the processing chamber for performing the post treatment process includes a hydrogen gas provided through a remote plasma source, such as the remote plasma source 124, 144. The gas flow for supplying the post treatment gas mixture is between about 0.15 sccm/L and about 60 sccm/L, such as between about 1 sccm/L and about 2 sccm/L, for example about 1 sccm/L and about 2 sccm/L. In the embodiment wherein the post treatment gas mixture utilizes hydrogen gas as the post treatment gas, the hydrogen gas may be supplied at about 0.15 sccm/L and about 60 sccm/L, such as about 1 sccm/L. The RF power supplied from the remote plasma source to do the post treatment process may be controlled at between about 15 milliWatts/cm² and about 300 milliWatts/cm², such as about 15 milliWatts/cm², may be provided to the showerhead 300 milliWatts/cm² and about 35 milliWatts/cm², such as about 70 milliWatts/cm² for post treatment and about 70 milliWatts/cm² for argon treatment. The process pressure may be controlled at between about 0.5 Torr and about 20 Torr. In other embodiments, the RF power for the post treatment process may be the same as utilized for the pre-treatment process.

Thus, the methods and apparatus described herein advantageously provide a method for forming and pre- and post treating a silicon containing with high film quality and low defect density. The silicon containing film formed from a remotely generated atomic hydrogen source has improved film electron mobility and low defect density, thereby providing a high electrical performance formed in the device structure in solar cell applications or thin film transistor device.

While the foregoing is directed to embodiments of the present invention, other and further embodiments of the invention may be devised without departing from the basic scope thereof, and the scope thereof is determined by the claims that follow.

1. A method for forming a silicon containing layer on a substrate comprising:
providing a substrate into a processing chamber;
providing a reacting gas mixture having a silicon containing gas into the processing chamber;
providing a hydrogen containing gas from a remote plasma source coupled to the processing chamber;
applying a RF power less than 17.5 mWatt/cm² to the processing chamber to form a plasma in the gas mixture; and
forming a silicon containing layer on the substrate.

2. The method of claim 1, wherein providing the gas mixture further comprises:
supplying a pretreatment gas mixture into the processing gas to perform a pretreatment process prior to supplying the gas mixture into the processing chamber.

3. The method of claim 2, wherein the pretreatment gas mixture is selected from the group consisting of hydrogen gas, H₂O gas, nitrogen gas, N₂O, NO₂, argon gas, helium gas, boron containing gas and phosphorous, and combinations thereof.

4. The method of claim 2, wherein the pretreatment gas mixture is supplied from a remote plasma source coupled to the processing chamber.

5. The method of claim 1, wherein forming the silicon containing layer on the substrate surface further comprises:
supplying a post treatment gas mixture into the processing gas to perform a post treatment process on the formed silicon containing layer.

6. The method of claim 5, wherein the post treatment gas mixture is selected from the group consisting of hydrogen gas, H₂O gas, nitrogen gas, N₂O, NO₂, argon gas, helium gas, boron containing gas and phosphorous, and combinations thereof.

7. The method of claim 6, wherein the post treatment gas mixture is supplied from a remote plasma source coupled to the processing chamber.

8. The method of claim 1, wherein the silicon containing layer is an intrinsic type microcrystalline silicon layer.

9. The method of claim 1, wherein the substrate has a p-type silicon containing layer formed thereon prior to transferring to the processing chamber.

10. An apparatus for forming a silicon containing layer for solar cell applications on a substrate comprising:
a chamber body defining a processing region;
a first remote plasma source configured to plasma dissociate a cleaning gas coupled to on the chamber body;
a second remote plasma source configured to plasma dissociate a processing gas coupled to the chamber body; and
at least conduit configured to supply the dissociated gas species from the first and the second remote plasma source through a gas distribution plate to the processing region.

11. The apparatus of claim 10, wherein the dissociated gas species from the first and the second remote plasma are separately supplied from different conduits through the gas distribution plate to the processing region; wherein the processing gas from the second remote plasma source is selected from a group consisting of hydrogen gas, H₂O gas, nitrogen gas, N₂O, NO₂, argon gas, helium gas, boron containing gas and phosphorous, and combinations thereof.

12. A method for forming a silicon containing layer on a substrate comprising:
providing a substrate into a processing chamber;
performing a pretreatment process on the substrate surface;
providing a reacting gas mixture having a silicon containing gas into the processing chamber;
providing a hydrogen containing gas from a remote plasma source coupled to the processing chamber;
applying a RF power less than 17.5 mWatt/cm² to the processing chamber to form a plasma in the gas mixture;
forming a silicon containing layer on the substrate; and
performing a post treatment process on the formed silicon containing layer.

13. The method of claim 12, wherein performing the pretreatment process further comprises:
supplying a pretreatment gas mixture into the processing gas, wherein the pretreatment gas is hydrogen gas.

14. The method of claim 13, wherein the pretreatment gas mixture is supplied from the remote plasma source coupled to the processing chamber.

15. The method of claim 12, wherein performing the post treatment process further comprises:
supplying a post treatment gas mixture into the processing gas, wherein the post treatment gas is hydrogen gas.

16. The method of claim 15, wherein the post treatment gas mixture is supplied from the remote plasma source coupled to the processing chamber.

17. The method of claim 16, wherein the silicon containing layer is an intrinsic type microcrystalline silicon layer.
